(19) United States
(12) Patent Application Publication
(10) Pub. No.: US 2008/0017402 A1
(43) Pub. Date: Jan. 24, 2008

(54) Substrate module with high thermal conductivity and its fabrication method of same

(75) Inventors: Rong-Fon Huang, Lung Tan Hsiang (TW); Hsu-Yuan Chang, Lung Tan Hsiang (TW); Kuo-Ta Wu, Lung Tan Hsiang (TW); Yulin Chiang, Lung Tan Hsiang (TW)

Correspondence Address: BACON & THOMAS, PLLC, 625 SLATERS LANE, FOURTH FLOOR, ALEXANDRIA, VA, 22314, US

(73) Assignee: INTEGRATED MODULE TECHNOLOGY INC., Lung Tan Hsiang (TW)

(21) Appl. No.: 11/822,772

(22) Filed: Jul. 10, 2007

(30) Foreign Application Priority Data
Jul. 7, 2006 (TW) 095124823

(51) Int. Cl. H05K 1/00

(52) U.S. Cl. 174/252

(57) ABSTRACT

A high thermal conductivity substrate includes multiple substrate material layers each having a first plane and a second plane opposite to the first plane, thermal conducting columns arranged in the substrate material layers and respectively extending through the first planes and second planes of each substrate material layer along its thickness direction, and multiple thermal conducting layers arranged on the first plane of each substrate material layer and the second plane of one substrate material layer that is to be disposed at the bottom side of the substrate and connected to the thermal conducting columns in the respective substrate material layers to form a horizontally and vertically distributed thermal conducting network.

### BACKGROUND OF THE INVENTION

1. Field of the Invention

The present invention relates to a substrate and its fabrication and more particularly, to a substrate with high thermal conductivity, which relates also to the fabrication of such a high thermal conductivity substrate.

2. Description of the Related Art

Because the market requirement of electronic product's function is more and more sophisticated, the number of functional electronic devices inside the electronic products is increased. However, continuously increasing the number of devices in the limited space of the product needs to increase the electronic device density on the circuit substrate. Normally, this aspect can be realized by means of SiP (System in Package).

The most commonly seen SiP is to connect a plurality of IC chip-like electronic devices to the top surface of a substrate for enabling these ICs to be electrically connected to a circuit board through the internal connection lines of the substrate. For heat dissipation, the substrate has arranged therein thermal conducting means. In consequence, there is a strong demand for increasing heat dissipation capability of the substrate.

FIG. 1 illustrates the heat dissipation structure of a existing substrate 1. The substrate 1 comprises 5 substrate material layers 11 that are laminated together, two horizontal thermal conducting layers 12 respectively arranged on a top side 111 and a bottom side 112 of the laminated substrate 1, and a plurality of thermal conducting columns 13 vertically extending through each substrate material layer 11 and in connection with the two horizontal thermal conducting layers 12. The thermal conducting layers 12 and the thermal conducting columns 13 are respectively formed of a thermal conductive material.

The horizontal thermal conducting layer 12 at the top side 111 of the substrate 1 has a bonding zone 121 for the bonding of electronic devices 2. The electronic devices 2 are bonded to the bonding zone 121 by means of Surface Mount Technology (SMT). During operation of the electronic devices 2, heat is transferred from the electronic devices 2 to the horizontal thermal conducting layer 12 at the top side 111 of the substrate 1 and then the vertical thermal conducting columns 13, and then transferred downwards through the vertical thermal conducting columns 13 to the horizontal thermal conducting layer 12 at the bottom side 112 of the substrate 1, and finally dissipated from the the horizontal thermal conducting layer 12 at the bottom side 112 of the substrate 1 to the outside.

However, the thermal conductive path of the aforesaid thermal conducting structure is simple and limited. The thermal transfer of this thermal conducting structure is limited to vertical direction. Therefore, this thermal conducting structure cannot provide sufficient heat dissipation area to effectively spread heat energy, lowering its heat dissipation efficiency.

Further, if the electronic devices 2 are IC chips bonded to the bonding zone 121 by means of eutectic bonding or flip-chip bonding, the flatness requirement for the bonding zone 121 is critical. Referring to FIG. 2, because of limitation of manufacturing process or different coefficients of thermal expansion, the junction between each vertical thermal conducting column 13 and the horizontal thermal conducting layer 12 is not flat (see the protruded portion in the drawing). This protrudded portion hinders full surface bonding of the IC chips to the bonding zone 121. Therefore, as shown in FIG. 3, the vertical thermal conducting columns 13 must be removed from the area of the substrate 1 corresponding to the bonding zone 12 so that the bonding zone 12 can achieve acceptable flatness.

As stated above, heat transfer from the substrate is made through the vertical thermal conducting columns 13. The reduction of thermal conducting column 13 reduces the heat dissipation power of the substrate 1.

Therefore, it is desirable to provide a substrate that eliminates the aforesaid problem.

### SUMMARY OF THE INVENTION

The present invention has been accomplished under the circumstances in view. It is the main objective of the present invention to provide a high thermal conductivity substrate with multiple thermally conductive path and area and achieves excellent heat dissipation efficiency. It is another objective of the present invention to provide a high thermal conductivity substrate, which is practical to fabricate which has multiple thermal conductivity path and area and achieves excellent heat dissipation efficiency.

According to the present invention, the high thermal conductivity substrate comprises a plurality of substrate material layers, each having a first plane and a second plane opposite to the first plane, a plurality of thermal conducting columns arranged in the substrate material layers and respectively extending through the first planes and second planes of the substrate material layers along the thickness direction, and a plurality of thermal conducting layers arranged on the first plane and/or second plane of each substrate material layer and connected to the thermal conducting columns in the respective substrate material layers such that when the substrate material layers are laminated and bonded togather, the thermal conducting layers and the thermal conducting columns are connected together.

According to the present invention, the high thermal conductivity substrate fabrication method comprises the steps of:

A) preparing a plurality of substrate material layers;

B) making a plurality of through holes on the substrate material layers at predetermined locations;

C) filling the through holes of the layers with a thermal conductive material to form a plurality of thermal conducting columns in the substrate material layers that extend to two opposite sides of the respective layers;

D) applying a thermal conductive material on at least one side of each substrate material layer to form a respective thermal conducting layer that is connected to the thermal conducting columns of the respective substrate material layers; and

E) stacking and laminating and sintering in the case of ceramic materials, the processed substrate material layers to form a substrate and to have the thermal conducting layers and columns of the substrate material layers be connected together.

### BRIEF DESCRIPTION OF THE DRAWINGS

FIG. 1 is a schematic drawing showing the heat dissipation structure of a substrate according to the prior art.

FIG. 2 is an enlarged view of a part of FIG. 1, showing the protruded portion hindered full surface bonding of an IC chip to the bonding zone.

FIG. 3 is a schematic drawing of the prior art design, showing thermal conducting columns removed from the area of the substrate below the bonding zone.

FIG. 4 is a schematic sectional view of a high thermal conductivity substrate in accordance with a first embodiment of the present invention.

FIG. 5 is a high thermal conductivity substrate manufacturing flow chart according to the present invention.

FIG. 6 is a perspective view of a part of the high thermal conductivity substrate according to the first embodiment of the present invention, showing the formation of the thermal conducting layer and thermal conducting columns in one substrate material layer.

FIG. 7 is a schematic sectional view of a high thermal conductivity substrate in accordance with a second embodiment of the present invention.

FIG. 8 is a schematic sectional view of a high thermal conductivity substrate in accordance with a third embodiment of the present invention.

FIG. 9 is a schematic sectional view of a high thermal conductivity substrate in accordance with a fourth embodiment of the present invention.

FIG. 10 is a top plain view of a high thermal conductivity substrate in accordance with a fifth embodiment of the present invention.

FIG. 11 is a schematic sectional view of the fifth embodiment of the present invention, showing heat energy transferred from the electronic devices through the thermal conducting columns around the bonding zone downwardly toward the other thermal conducting layers and thermal conducting columns.

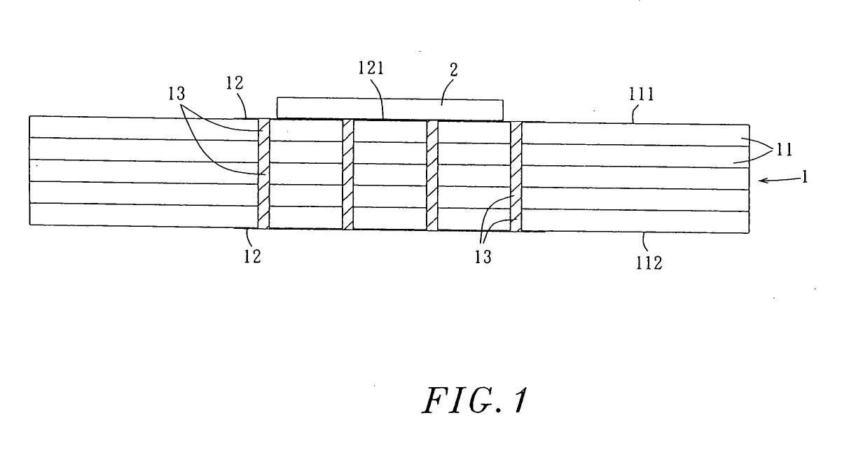

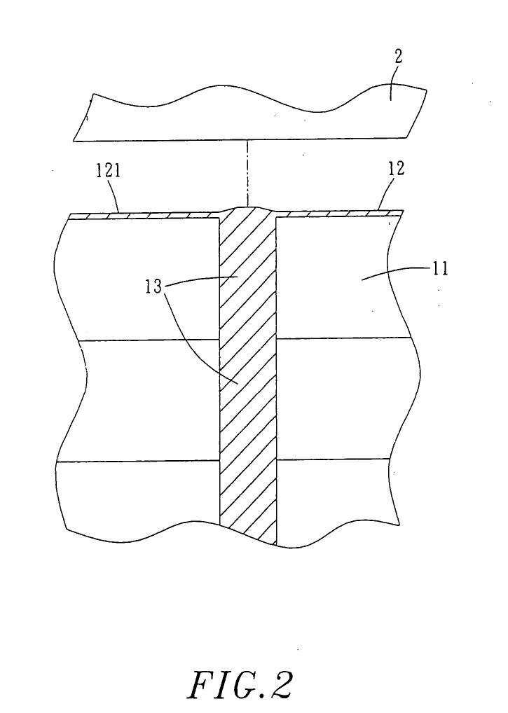

### DETAILED DESCRIPTION OF THE PREFERRED EMBODIMENT

Before detailed description of the present invention, it is to be understood that the reference numbers indicate like parts through out the various different preferred embodiments of the present invention.

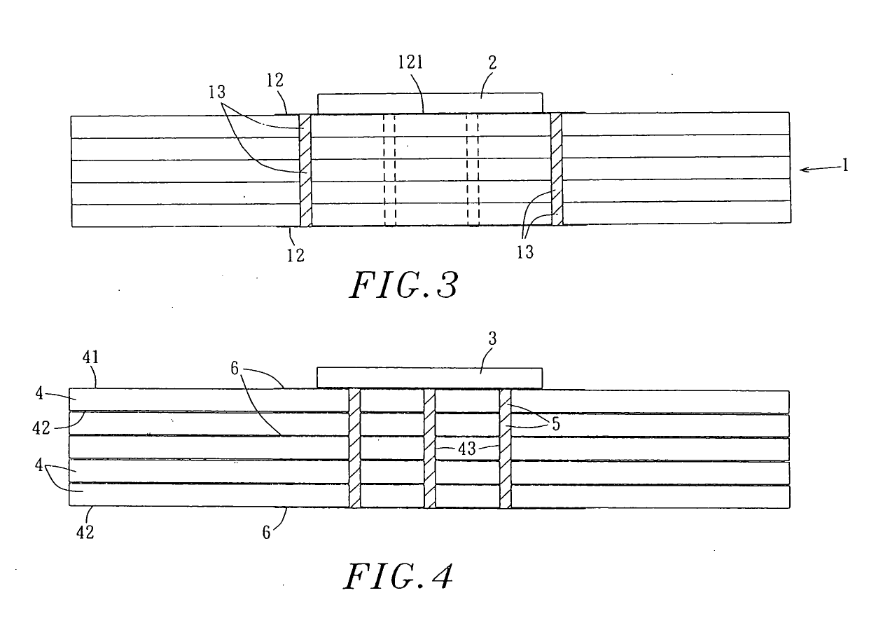

Referring to FIG. 4, a high thermal conductivity substrate in accordance with a first embodiment of the present invention is shown comprised of 5 substrate material layers 4, multiple thermal conducting columns 5, and 6 thermal conducting layers 6. The high thermal conductivity substrate carries an electronic device 3. During operation of the electronic device 3, the thermal conducting columns 5 and the thermal conducting layers 6 dissipate heat from the electronic device 3. The electronic device 3 reference here can be either light emitting diode (LED) chips, microprocessor IC, power amplify IC or any IC that generate heat during operation.

Unless particularly specified, the substrate material layers 4 in the following preferred embodiments are made out of ceramics, i.e., the substrate material layers 4 can be HTCC (High Temperature Co-fired Ceramic) or LTCC (Low Temperature Co-fired Ceramic) ceramic tapes before sintering. These two types of substrate material layers 4 are processed in the same manner in the present invention. In actual practice, the substrate material layers 4 can be PCBs (Printed Circuit Boards), IMSs (Insulated Metal Substrates) or any other equivalent products.

Every substrate material layer 4 has a first plane 41, a second plane 42 opposite to the first plane 41, and a plurality of through holes 43 formed through the two planes 41 and 42 along thickness direction. The thermal conducting columns 5 are formed in the through holes 43.

According to this embodiment, the thermal conducting layers 6 are respectively formed on the first planes 41 of every substrate material layer 4 and also on the second plane 42 of the bottom substrate material layer 4. The thermal conducting layers 6 are connected to the thermal conducting columns 5 on the same substrate material layer 4. The manufacturing method and principle of the thermal conducting structure are described hereinafter.

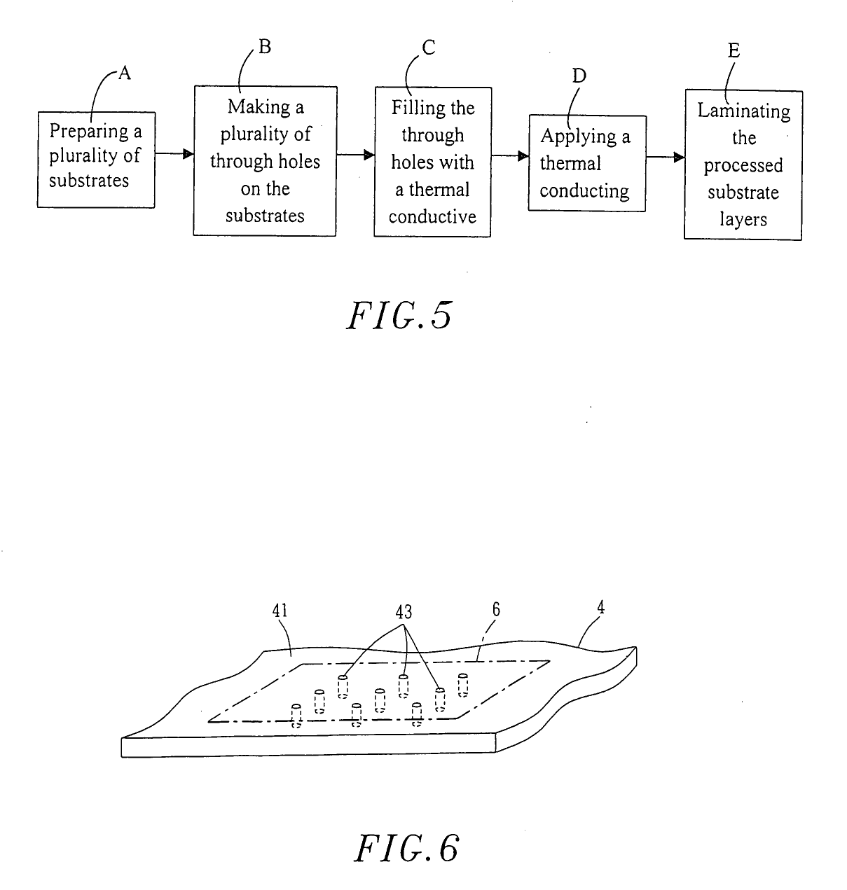

As shown in FIGS. 5 and 6, the fabrication of the aforesaid thermal conducting structure comprises the steps of (A) prepare a predetermined number of ceramic tape layers 4, (B) punching through holes 43 through first and second planes 41 and 42 of each of the ceramic tape layers 4 at predetermined locations, (C) filling the through holes 43 with a thermal conducting metal paste to form thermal conducting columns 5 that extend through the two opposite sides of each ceramic tape layer 4, (D) printing a thermal conducting layer 6 on the first plane 41 of each ceramic tape layer 4 to connect the thermal conducting layer 6 to the thermal conducting columns 5 in each ceramic tape layer 4, and finally, (E) stacking and laminating the ceramic tape layers 4 to form a ceramic substrate by means of compression and followed by a sintering process to densified the ceramic substrate.

It is to be understood that the bottom-sided ceramic tape layer 4 has its first plane 41 and second plane 42 respectively covered with a respective thermal conducting layer 6. The thermal conducting material for the thermal conducting layers 6 is a printable metal paste. Therefore, when performing step (C) and step (D), the thermal conducting layer 6 on ceramic tape layer 4 makes contact connection with the thermal conducting columns 5. Further, because the multiple ceramic tape layers 4 are stacked and laminated together by means of heat and compression, the thermal conducting columns 5 that exposed to the second planes 42 bond to the thermal conducting layer 6 on the first planes 41 of the next ceramic tape layer 4. When the laminated ceramic layers 4 are sintered and densified, the thermal conducting columns 5 on one upper substrate 4 are bonded to the thermal conducting layer 6 on one lower substrate 4. Therefore, after the ceramic tape layers 4 are sintered together, the thermal conducting layers 6 and the thermal conducting columns 5 are bonded together, forming a continuous connection structure.

Further, if printed circuit boards are used for the substrate material layers 4, adhesive means can be used with heating and compression process to bond the substrate material layers 4, without the sintering step. When other materials are used for the substrate material layers 4, the layers 4 can be bonded together by means of a respective suitable bonding process. Because available techniques of laminating the substrate material layers 4 are obvious to any person skilled in the art, no further detailed description in this regard is necessary.

According to the aforesaid design, the electronic device 3 is carried on the thermal conducting layer 6 at the first plane 41 of the topmost substrate material layer 4, and the heat energy produced during operation of the electronic device 3 is guided downwards through the cross-linked thermal conducting columns 5 and the thermal conducting layers 6. When compared to conventional designs, the invention has a vertical thermal conductive path as well as a horizontal thermal conductive path; therefore the thermal conducting structure of the present invention is superior to the conventional designs and can effectively dissipate heat energy from the electronic device 3.

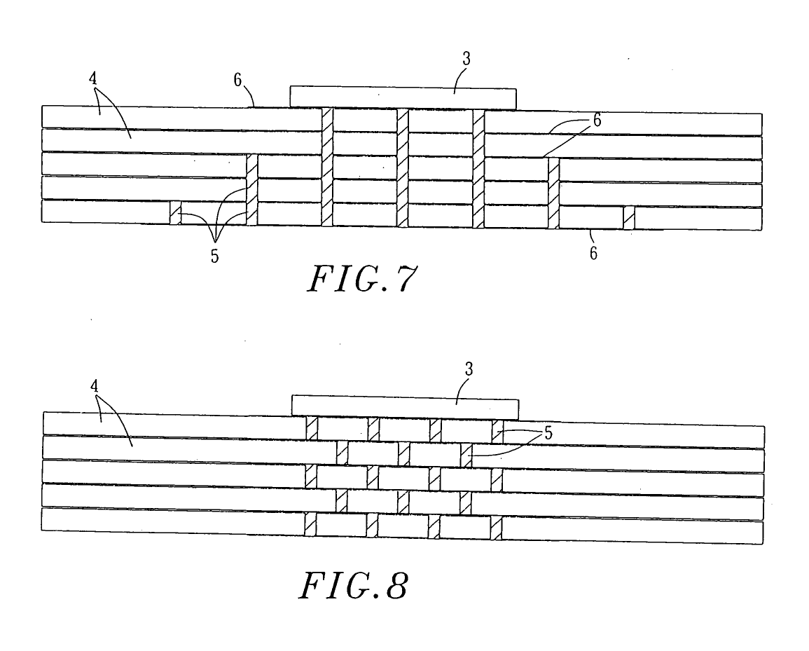

FIG. 7 illustrates a high thermal conductivity substrate in accordance with a second embodiment of the present invention. Similar to the aforesaid first embodiment, the high thermal conductivity substrate of this second embodiment is also comprised of 5 substrate material layers 4, a plurality of thermal conducting columns 5, and 6 thermal conducting layers 6. The difference between the aforesaid first embodiment and this second embodiment is that the thermal conducting columns 5 according to the aforesaid first embodiment cover the same area for every substrate material layer when looking at the cross sectional view; the thermal conducting columns 5 according to this second embodiment cover larger area toward the bottom substrate layers, showing a pyramidal pattern. This second embodiment shows that the thermal conductive path and thermal conductive area of the thermal conducting structure can be adjusted subject to the heat generating amount or characteristics of the electronic device 3. If the electronic device 3 generates a large amount of heat during operation, the number of the thermal conducting columns 5 and the distribution area of the thermal conducting layers 6 on the material layers 4 can be relatively increased.

FIGS. 8 and 9 illustrate a high thermal conductivity substrate in accordance with a third embodiment of the present invention and a high thermal conductivity substrate in accordance with a fourth embodiment of the present invention respectively. According to these two embodiments, the thermal conducting columns 5 in each two vertically spaced adjacent material layers 4 are arranged in a staggered manner, i.e., the thermal conducting structure dissipates heat from the electronic device 3 to the bottom side of the high thermal conductivity substrate not through one single vertical direction only. These two embodiments enable the generated heat energy to be transferred from the electronic device 3 toward the bottom side of the substrate more evenly.

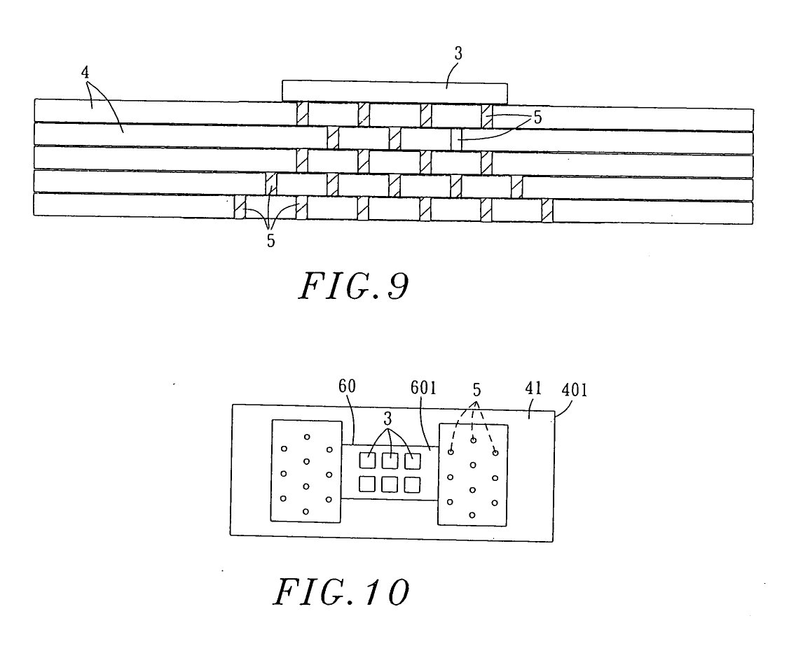

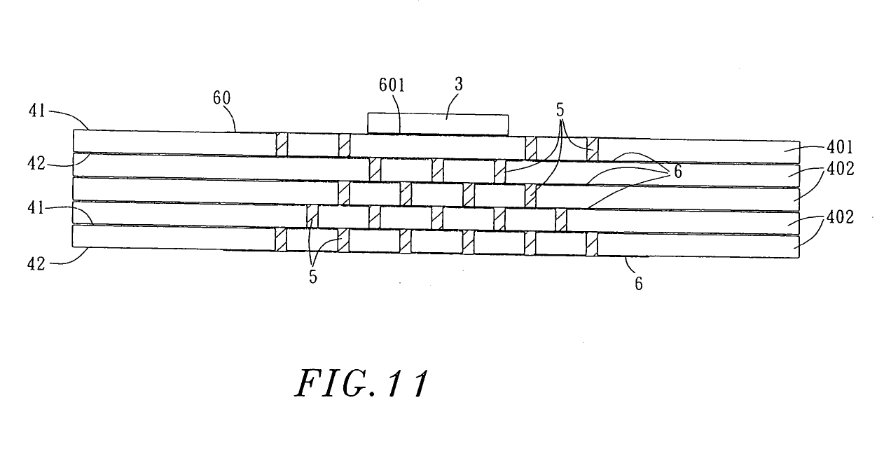

FIGS. 10 and 11 illustrate a high thermal conductivity substrate in accordance with a fifth embodiment of the present invention. This embodiment is suitable for an electronic device 3 that requires high substrate flatness in bonding. According to this embodiment, the electronic device 3 is an IC chip bonded to a bonding zone 601 of the substrate by means of eutectic bonding or flip-chip bonding.

According to this fifth embodiment, the high thermal conductivity substrate is comprised of 5 substrate material layers 4, a mounting layer 60, a plurality of thermal conducting columns 5, and 6 thermal conducting layers 6. The materials and formation methods of the substrate material layers 4, the thermal conducting columns 5, and the thermal conducting layers 6 are same as the aforesaid various embodiments of the present invention. For easy understanding of the description of this fifth embodiment, the topmost material layer 4 is defined to be the first substrate material layer 401 and the other substrate material layers 4 are defined to be the second substrate material layers 402; the topmost thermal conducting layer 6 is defined to be the mounting layer 60 and the terminology of the other thermal conducting layers 6 remains unchanged.

Every substrate material layer 4 has a first plane 41, and a second plane 42 opposite to the first plane 41. The second substrate material layers 402 are arranged below the second plane 42 of the first substrate material layer 401 when stacking.

The mounting layer 60 is arranged on the first plane 41 of the first substrate material layer 401, providing at least one bonding zone 601 for the bonding of one or a number of electronic devices 3 and for transferring heat from the electronic device(s) 3. It is to be understood that the at least one bonding zone 601 is for the bonding of at least one electronic device 3. The number and size of the bonding zone 601 are determined subject to the number, type, size or circuit layouts of the electronic device 3. According to this embodiment, the mounting layer 60 has one single bonding zone 601 for the mounting of multiple electronic devices 3.

The thermal conducting layers 6 are arranged on the first planes 41 of the second substrate material layers 402. The thermal conducting columns 5 are arranged in the layers 401 and 402 along the thickness direction of the layers 401 and 402 and extending through the opposite planes 41 and 42 of the respective layers 401 and 402. It is to be understood that the flatness control of the junction between the thermal conducting columns 5 and the mounting layer 60 (thermal conducting layer 6) is difficult (as stated before). Therefore, the thermal conducting columns 5 are eliminated from the area of the first layer 401 beneath the bonding zone 601 when the substrate is designed, i.e., the thermal conducting columns 5 are arranged in the first layer 401 beyond the bonding zone 601 so that the first layer 401 has a flat bonding zone 601.

When the substrate material layers 401 and 402 are bonded together, the mounting layer 60, the thermal conducting layers 6 and the thermal conducting columns 5 are connected. Thus, the substrate has a flat bonding zone 601, and heat generated by the electronic device 3 can be transferred from the mounting layer 60 to the thermal conducting columns 5 in the first substrate material layer 401 around the bonding zone 601 and then transferred downwards to the thermal conducting layer 6 and thermal conducting columns 5 of the second substrate material layers 402.

This fifth embodiment derived from the aforesaid fourth embodiment. When compared to the prior art designs, this fifth embodiment has additionally a thermal conductive path in horizontal direction. Although the thermal conducting columns 5 are not directly provided at the bottom side of the bonding zone 601, heat energy can still be transferred through the thermal conducting columns 5 around the bonding zone 601 to the beneath cross-linked thermal conducting network, eliminating the drawback of great loss of heat dissipation power of the prior art design when either vertical thermal conducting column 5 is removed.

In conclusion, the high thermal conductivity substrate and its fabrication uses vertical thermal conducting columns 5 and horizontal thermal conducting layers 6 to constitute an excellent thermal conducting path that effectively transfers and spreads heat energy. Further, by means of the aforesaid function, the present invention is suitable for carrying electronic devices 3 that require perfect leveling, and can effectively dissipate heat from the electronic device(s) 3 installed therein.

Although particular embodiments of the invention have been described in detail for purposes of illustration, various modifications and enhancements may be made without departing from the spirit and scope of the invention. Accordingly, the invention is not to be limited except as by the appended claims

What the invention claimed is:

1. A high thermal conductivity substrate comprising:
a plurality of substrate material layers, said substrate material layers each having a first plane and a second plane opposite to said first plane;
a plurality of thermal conducting columns arranged in said substrate material layers and respectively extending through the first planes and the second planes along the thickness direction of said material layers; and
a plurality of thermal conducting layers arranged on the first plane and the second plane of each of said substrate material layers and connected to the thermal conducting columns in the respective substrate material layers such that when said substrate material layers are laminated, said thermal conducting layers and said thermal conducting columns are connected together.

2. The high thermal conductivity substrate as claimed in claim 1, wherein said substrate material layers are one of printed circuit board, insulated metal substrate, high temperature co-fired ceramic and low temperature co-fired ceramic.

3. The high thermal conductivity substrate as claimed in claim 1, wherein said substrate material layers each have a plurality of through holes connecting the respective first planes and second planes for the forming of said thermal conducting columns; and the location and number of said thermal conducting columns on each substrate material layer can be different.

4. The high thermal conductivity substrate as claimed in claim 1, wherein said thermal conducting layers and said thermal conducting columns are respectively formed of a printable metal material.

5. A high thermal conductivity substrate for transferring heat from at last one electronic device carried thereon, the high thermal conductivity substrate comprising:
a first substrate material layer, said first substrate material layer having a first plane and a second plane opposite to the first plane;
a plurality of second substrate material layers arranged in a stack on the second plane of said first substrate material layer, said second substrate material layers each having a first plane and a second plane opposite to the first plane;
a mounting layer arranged on the first plane of said first substrate material layer, said mounting layer providing a bonding zone for the mounting of said at least one electronic device and for transferring heat from said at least one electronic device;
a plurality of thermal conducting layers arranged on the first plane and second planes of each of said second substrate material layers; and
a plurality of thermal conducting columns arranged in said first substrate material layer and said second substrate material layers and respectively extending through the first planes and second planes of said first and second substrate material layers along the thickness direction of said first and second substrate material layers, the thermal conducting columns that are arranged in said first substrate material layer being disposed beyond said bonding zone, said thermal conducting columns being connected to said thermal bonding layers such that when said first substrate material layer and said second substrate material layers are laminated, said mounting layer, said thermal conducting layers and said thermal conducting columns are connected together.

6. The high thermal conductivity substrate as claimed in claim 5, wherein said first substrate material layer and said second substrate material layers are one of printed circuit board, insulated metal substrate, high temperature co-fired ceramic and low temperature co-fired ceramic.

7. The high thermal conductivity substrate as claimed in claim 5 wherein said first substrate material layer and said second substrate material layers each have a plurality of through holes connecting the respective first planes and second planes for the forming of said thermal conducting columns; and the location and number of said thermal conducting columns on each substrate material layer can be different.

8. The high thermal conductivity substrate as claimed in claim 5, wherein said thermal conducting layers and said thermal conducting columns are respectively formed of a printable metal material.

9. A high thermal conductivity substrate fabrication method comprising the steps of:
A) preparing a plurality of substrate material layers;
B) making a plurality of through holes on said substrate material layers at predetermined locations;
C) filling the through holes of said substrate material layers with a thermal conductive material to form a plurality of thermal conducting columns in said substrate material layers that extend to two opposite sides of the respective substrate material layers;
D) applying a thermal conductive material on at least one side of each of said substrate material layers to form a respective thermal conducting layer on each of said substrate material layers and connecting the thermal conducting layer of each of said substrate material layer to the thermal conducting columns of the respective substrate material layers; and
E) stacking and laminating the processed substrate material layers to form a substrate and to have said thermal conducting layers and said thermal conducting columns of said substrate material layers be connected together.

10. The high thermal conductivity substrate fabrication method as claimed in claim 9, wherein the substrate material layers in step A) are one of high temperature co-fired ceramic and low temperature co-fired ceramic.

11. The high thermal conductivity substrate fabrication method as claimed in claim 10, wherein said substrate material layers are laminated in step E) to form a substrate by means of compression and sintering process.

12. The high thermal conductivity substrate fabrication method as claimed in claim 9, wherein the substrate material layers in step A) are one of printed circuit board and insulated metal substrate.

13. The high thermal conductivity substrate fabrication method as claimed in claim 12, wherein said substrate material layers are laminated in step E) to form a substrate by means of compression process.

14. The high thermal conductivity substrate fabrication method as claimed in claim 9, wherein the thermal conductive material used in step C) and D) is a printable metal material.
